(19) United States
(12) Patent Application Publication
(10) Pub. No.: US 2018/0183384 A1
(43) Pub. Date: Jun. 28, 2018

(54) PHOTOVOLTAIC POWER GENERATING APPARATUS

(71) Applicant: NABELL CORPORATION, Iga-shi, Mie (JP)

(72) Inventors: Norio Nagai, Iga-shi, Mie (JP); Hirotoshi Miyake, Iga-shi, Mie (JP)

(21) Appl. No.: 15/307,207

(22) PCT Filed: Jun. 11, 2015
(86) PCT No.: PCT/JP2015/066806

§ 371 Date: Oct. 27, 2016

(30) Foreign Application Priority Data
Jun. 30, 2014 (JP) 2014-134789

(51) Int. Cl. H02S 30/20; H01L 31/0445; H02S 40/34

(52) U.S. Cl. CPC H02S 30/20; H02S 40/34; H01L 31/0445

(57) ABSTRACT

Disclosed is a photovoltaic power generating apparatus which includes a terminal box 12 disposed on a terminal box fixing part 3 disposed on a base 2; and upper and/or lower generator(s), or, left and/or right generator(s) 4 to 11 individually formed into a quadrangular shape, including a single photovoltaic power generator, disposed in at least two directions out of four directions including upper, lower and other directions around the terminal box fixing part; or, upper and/or lower generator(s), or, left and/or right generator(s) individually including a single photovoltaic power generator group that includes a plurality of photovoltaic power generators and formed into a quadrangular shape as a whole, wherein all of the generators 4 to 11 are stackable by folding on the top face side or the back face side of the terminal box fixing part 3.

### TECHNICAL FIELD

This invention relates to a photovoltaic power generating apparatus, and in particular to a photovoltaic power generating apparatus that is composed of a plurality of photovoltaic power generators such as photovoltaic panels or photovoltaic films, and is made foldable between the adjacent photovoltaic power generators.

### BACKGROUND ART

Supported by foundation of the national electricity purchasing scheme in Japan, it has been a well-known practice to install a large number of photovoltaic power generating apparatuses on roofs or rooftops of houses, buildings or factories, or in large sites. Most of the photovoltaic power generating apparatuses, thus installed on the structures or in the sites, are configured so that modules each composed of a plurality of cells are arranged in a predetermined area to form a photovoltaic power generator (solar panel, etc.), and the photovoltaic power generator is supported by a frame in an inclined manner. Meanwhile, some of the photovoltaic power generating apparatuses have long been used as power units for electronic calculators, and recently as batteries for charging mobile phones or other home appliances.

Now, the photovoltaic power generating apparatuses installed as described above on the structures or in the sites are fixed to such structures or the like, and are therefore not portable, meanwhile the photovoltaic power generating apparatuses marketed for charging home appliances are small and therefore portable, but can produce only a small amount of electric power. In short, there has been a need for a photovoltaic power generating apparatus that is portable to a place where utility power is not accessible, or to a place where a power supply system became non-accessible due to natural disaster including earthquake disaster, and can create a necessary quantity of power generation.

Accordingly, various types of photovoltaic power generating apparatus thus functionalized have been proposed as enumerated below. In an exemplary apparatus, rigid panels, having a photovoltaic film fixed on the top face thereof, are joined using hinges in a specific direction to make the apparatus foldable by outward folding and inward folding repeated alternately at positions where the individual hinges are fixed, wherein the photovoltaic films are vertically stacked in the folded state, and the individual top faces of the photovoltaic films are held flat in the unfolded state (see Patent Literature 1). There has been proposed another apparatus in which a plurality of photovoltaic panels are fixed on the top face of a flexible base, making the apparatus foldable at portions of the flexible base between the adjacent ones of the plurality of photovoltaic panels (Patent Literature 2).

### CITATION LIST

### Patent Literature

[Patent Literature 1] JP-A-2012-134462

[Patent Literature 2] JP-U-3177813

### SUMMARY OF THE INVENTION

### Technical Problem

Now, in the individual photovoltaic power generating apparatuses disclosed in Patent Literatures 1 and 2, the individual photovoltaic power generators such as photovoltaic films or photovoltaic panels are connected in such a way that the individual positive terminals and the individual negative terminals formed thereon are electrically connected respectively by wiring, and then respectively connected to a positive cable and a negative cable for external output. The positive cable and the negative cable are connected to an electronic equipment such as battery, inverter (power conditioner) or the like.

Accordingly, in the above-described photovoltaic power generating apparatuses disclosed in Patent Literatures 1 and 2, the wirings that respectively connect the individual photovoltaic power generators arrayed in a specific direction will become very long, and this increases electric resistance. Another problem is that, the larger the number of the photovoltaic power generators will be, the more frequently the folding action should occur, and this increases a risk of disconnection in midway of the wirings.

This invention is therefore proposed aiming at solving the above-described problems in the conventional photovoltaic power generating apparatuses, and is to provide a novel photovoltaic power generating apparatus that is not only foldable and highly portable, but also can reduce the electric resistance as a result of shortening the wirings, and can prevent the wirings from being disconnected in midway.

### Solution to Problem

This invention is proposed aiming at solving the problems described above. A first invention (the invention described in Claim 1) relates to a photovoltaic power generating apparatus which includes: a base composed of a foldable sheet body such as cloth, resin sheet or the like; a quadrangular terminal box fixing part disposed on the base; a terminal box disposed either on the top face or the back face of the terminal box fixing part; and upper and/or lower generator(s), or, left and/or right generator(s) individually formed into a quadrangular shape, which include(s) a single photovoltaic power generator, and disposed on the top face of the base in at least two directions out of four directions including upper, lower, left and right directions around the terminal box fixing part; or, upper and/or lower generator(s), or, left and/or right generator(s) individually including a single photovoltaic power generator group that includes a plurality of photovoltaic power generators and formed into a quadrangular shape as a whole, where all of the generators are stackable by folding on the top face side or the back face side of the terminal box fixing part.

According to the first invention, the generators that generate electric power under sunlight are disposed in at least two directions out of four directions including upper, lower, left and right directions around the terminal box fixing part having the terminal box disposed thereon. Modes of arrangement of the generators in at least two directions include the following:
(A) having the generators disposed respectively on both of the upper side and the lower side (two directions) of the terminal box fixing part;
(B) having the generators disposed respectively on both of the left side and the right side (two directions) of the terminal box fixing part;
where, modes (A) and (B) are, in other words, the modes respectively having the terminal box fixing part disposed between the upper generator and the lower generator, or, between the left generator and the right generator,
(C) having the generators disposed either on the upper side or the lower side of the terminal box fixing part, and either on the left side or the right side of the terminal box fixing part (two directions in total);
(D) having the generators disposed on both of the upper side and the lower side of the terminal box fixing part, and either on the left side or the right side of the terminal box fixing part (three directions in total);
(E) having the generators disposed on both of the left side and the right of the terminal box fixing part, and either on the upper side or the lower side of the terminal box fixing part (three directions in total);
(F) having the generators disposed on both of the left side and the right side of the terminal box fixing part, and on both of the upper side and the lower side of the terminal box fixing part (four directions),
where, with the individual generators disposed according to any of modes (A) to (F), each base will have an area and a geometry collectively corresponded to the area and geometry of the terminal box fixing part and the overall area and geometry of all generators.

According to the photovoltaic power generating apparatus of the first invention, not only that all the generators may be positioned (stacked) above the terminal box fixing part by folding the base per se, but also that total distance between the terminal box and each of the photovoltaic power generators will be shorter than the total distance in the conventional photovoltaic power generating apparatus having the individual photovoltaic power generators aligned in parallel in one direction. Since the total length of the wirings that electrically connect the terminal box with each of the photovoltaic power generators composing the generator may be shortened in this way, so that the electric resistance may greatly be suppressed. In the first invention, in the process of stacking (by folding) the individual generators so as to place them above the terminal box fixing part, or in the process of unstacking the generators having been stacked above the terminal box fixing part, since the wirings between the terminal box and the individual generators are stacked or unstacked at only one portion, so that the wirings between the terminal box fixing part and the individual generators may greatly be relieved from the risk of disconnection.

The base composing the first invention will suffice if it is made of a foldable sheet body such as cloth, resin sheet, synthetic leather or the like. The cloth is exemplified by woven fabric and nonwoven fabric. The resin sheet is preferably selected, without special limitation, from the materials at least unlikely to break or crack due to fatigue after repetitive folding, and may even be a laminate of two or more kinds of resin sheet. The terminal box fixing part is a portion where parts of the wirings from the individual generators to the terminal box are laid.

As described above, each of the generators may be composed of a single photovoltaic power generator formed into a quadrangular shape, or, may be composed of a single photovoltaic power generator group that is composed of a plurality of photovoltaic power generators, and formed into a quadrangular shape as a whole. Of course, the photovoltaic power generator, or simply the generator, composing this invention will suffice if it can convert, under solar irradiation, solar energy into electric energy (power generation), and may be configured as any of a single cell, module, or array. The photovoltaic power generator may also be any of those using discrete single-crystalline or polycrystalline silicon substrates (single crystalline silicon solar cell, crystalline silicon solar cell); amorphous silicon solar cell having an amorphous silicon film formed on a substrate made of glass, metal or the like; and compound semiconductor solar cell using a plurality of elements (single crystalline compound semiconductor solar cell, polycrystalline compound semiconductor solar cell). The number of the photovoltaic power generators, composing a single photovoltaic power generator group that is formed (as a whole) into a quadrangular shape, is selectable depending on the size of the individual photovoltaic power generators, and an available space of the base on which a single photovoltaic power generator group is placed. For example, two rectangular solar generators may be arranged side by side, in such a way the long sides of the photovoltaic films are laid in parallel.

A second invention (the invention described in Claim 2) relates to the photovoltaic power generating apparatus according to the first invention, which further includes a diagonal generator disposed on the top face of the base, in any one direction out of four directions including obliquely upper left, obliquely lower left, obliquely upper right and obliquely lower right directions around the terminal box fixing part, a predetermined distance away from the upper and/or lower generator(s), or, left and/or right generator(s).

Referring now to the modes of arrangement of the individual generators in the photovoltaic power generating apparatus according to the first invention, the second invention typically includes the modes enumerated as follows:
(G) having the generators disposed respectively on both of the upper side and the lower side of the terminal box fixing part (two directions); and having the diagonal generator disposed on the left side or the right side of the generator thus disposed on the upper side or the lower side;
(H) having the generators disposed respectively on both of the left side and the right side of the terminal box fixing part (two directions), and having the diagonal generator disposed either on the upper side of the lower side of the generator thus disposed on the left side of the right side;
(I) having the generators disposed respectively either on the upper side and the lower side of the terminal box fixing part, and either on the left side and the right side of the terminal box fixing part; and having the diagonal generator disposed either on the obliquely upper left side or the obliquely lower left side of the terminal box fixing part, or either on the obliquely upper right side or the obliquely lower right side thereof;
(J) having the generators disposed respectively on both of the upper side and the lower side of the terminal box fixing part, and either on the left side or right side of the terminal box fixing part (three directions); and having the diagonal generator disposed either on the obliquely upper left side or the obliquely lower left side of the terminal box fixing part, or either on the obliquely upper right side or the obliquely lower right side thereof;
(K) having the generators disposed respectively on both of the left side and the right side of the terminal box fixing part, and either on the upper side or the lower side of the terminal box fixing part (three directions); and having the diagonal generator disposed either on the obliquely upper left side or the obliquely lower left side of the terminal box fixing part, or either on the obliquely upper right side or the obliquely lower right side thereof; and
(L) having the generators disposed respectively on both of the left side and the right side of the terminal box fixing part, and on both of the upper side and the lower side of the terminal box fixing part (four directions); and having the diagonal generator disposed either on the obliquely upper left side or the obliquely lower left side of the terminal box fixing part, or either on the obliquely upper right side or the obliquely lower right side thereof.

The photovoltaic power generating apparatus of the second invention, additionally having the diagonal generator, can increase the amount of power generation, and the length of the wirings from the individual generators to the terminal box may be shortened. Another advantage is that only one each action will suffice for stacking (by folding) the diagonal generator above or behind the terminal box fixing part, and for unstacking the stacked diagonal generator respectively for modes (G) and (H), and one or two actions will suffice respectively for modes (I) to (L). In short, in the photovoltaic power generating apparatus of the second invention, when the diagonal generator is stacked above or behind the terminal box fixing part, the wiring routed from the diagonal generator to the terminal box will be folded at two points at most, meanwhile in the conventional apparatus (having the same number of generators as those described above) having the photovoltaic power generators aligned in parallel in one direction, the wirings routed to the terminal box will be folded at a larger number of points. According to this invention, it now becomes possible to effectively avoid a risk of disconnection of the wirings in midway, after repetitive folding and unfolding.

Note that a space between the diagonal generator and the generator on the upper side or the lower side, or on the left side or the right side, is a portion where the wiring for electrically connecting each photovoltaic power generator and the terminal box, and will therefore suffice if it has a width suitable for wiring.

A third invention (the invention described in Claim 3) relates to the photovoltaic power generating apparatus according to the first or second invention, wherein the base has a quadrangular external shape, the terminal box fixing part is disposed at the center of the base, and the individual generators are disposed so as to surround the terminal box fixing part.

Since the photovoltaic power generating apparatus of the third invention has the terminal box fixing part disposed at the center of the base, and has the individual generators disposed so as to surround the terminal box fixing part, so that the apparatus has eight in total of generators itemized by the generators on the upper side and the lower side, the generators on the left side and the right side, and four in total of diagonal generators on the upper left, lower left, upper right and lower right of the terminal box fixing part. Accordingly the apparatus, having a larger number of generators as compared, with those composing the first or second invention, can increase the amount of power generation. Since the folding for stacking the four diagonal generators above or behind the terminal box fixing part needs only two actions, so that the wirings may greatly be relieved from the risk of disconnection, like the inventions explained previously.

A fourth invention (the invention described in Claim 4) relates to a photovoltaic power generating apparatus which includes: a terminal box fixing part formed into a quadrangular shape; a terminal box disposed either on the top face or the back face of the terminal box fixing part; upper and/or lower base(s), or, left and/or right base(s) disposed in at least two directions out of four directions including upper, lower, left and right directions around the terminal box fixing part, individually formed into a quadrangular shape and in a plate form, and joined with the terminal box fixing part using hinges or flexible sheet bodies; and generators respectively disposed on the top faces of the individual bases, each including a single photovoltaic power generator; or, generators each including a single photovoltaic power generator group that includes a plurality of photovoltaic power generators and formed into a quadrangular shape as a whole, where all of the bases are foldable on the top face side or the back face side of the terminal box fixing part.

As compared with the first invention, the fourth invention is different in that the base, on which the individual generators are disposed, is made independent from the terminal box fixing part but joined therewith using hinges or a flexible sheet bodies, and in that the generators are disposed respectively on these bases, rather than using an integrated base composing the first invention. The residual configuration is substantially same.

Accordingly, also the fourth invention can give the same operations and effects as the first invention.

The individual bases composing the fourth invention will suffice if they are respectively formed into a quadrangular form and into a plate form, and is preferably as thin as possible.

A fifth invention (the invention described in Claim 5) relates to the photovoltaic power generating apparatus according to Claim 4, which further includes a diagonal base joined to the upper and/or lower base(s), or, to the left and/or right base(s) using a hinge or a flexible sheet body, in any one direction out of four directions including obliquely upper left, obliquely lower left, obliquely upper right and obliquely lower right directions around the terminal box fixing part, and, the diagonal base has, disposed on the top face thereof, a generator including a single photovoltaic power generator, or, a generator including a single photovoltaic power generator group that includes a plurality of photovoltaic power generators and formed into a quadrangular shape as a whole.

The fifth invention is derived by limitation from the fourth invention, and is characterized by addition of the diagonal base as a result of using the discrete bases as a constituent in the fourth invention, in place of using the base composing the first invention, so that the fifth invention, when compared with the second invention derived by limitation from the first invention, is not substantially different from the second invention.

Accordingly, also the fifth invention can give the same operations and effects as the second invention.

A sixth invention (the invention described in Claim 6) relates to the photovoltaic power generating apparatus according to the fourth invention or fifth invention, wherein the bases that are respectively joined using the hinges or the flexible sheet bodies collectively have a quadrangular external shape as a whole, and the terminal box fixing part is disposed at the center of the whole bases.

Since the sixth invention is derived by limitation from the fourth or fifth invention, and is given as a result of using the discrete bases as a constituent in the fourth invention, in place of using the base composing the first invention, so that the sixth invention is not substantially different from the third invention.

Accordingly, also the sixth invention can give the same operations and effects as the third invention.

### Advantageous Effects of Invention

According to the photovoltaic power generating apparatus of the first invention (the invention described in Claim 1), not only that all the generators may be positioned (stacked) above or behind the terminal box fixing part by folding the base per se, but also that total distance between the terminal box and each of the photovoltaic power generator will be shorter than the total distance in the conventional photovoltaic power generating apparatus having the individual photovoltaic power generators aligned in parallel in one direction. Since the total length of the wirings that electrically connect the terminal box with each of the photovoltaic power generators composing the generator may be shortened in this way, so that the electric resistance may greatly be suppressed. In the first invention, in the process of stacking (by folding) the individual generators so as to place them above or behind the terminal box fixing part, or in the process of unstacking the generators having been stacked above or behind the terminal box fixing part, since the wirings between the terminal box and the individual generators are stacked or unstacked at only one portion, so that the wirings between the terminal box fixing part and the individual generators may greatly be relieved from the risk of disconnection. Also the fourth invention (the invention described in Claim 4) can give the same effects as the first invention.

According to the photovoltaic power generating apparatus of the second invention (the invention described in Claim 2), additionally having the diagonal generator in addition to the generators composing the first invention, the amount of power generation may be increased, and the length of the wirings from the individual generators to the terminal box may be shortened. Another advantage is that two actions at most will suffice for stacking (by folding) the diagonal generator above or behind the terminal box fixing part and for unstacking the stacked diagonal generator. In short, in the photovoltaic power generating apparatus of the second invention, when the diagonal generator is stacked above or behind the terminal box fixing part, the wiring routed from the diagonal generator to the terminal box will be folded at two points at most, meanwhile in the conventional apparatus (having the same number of generators as those described above) having the photovoltaic power generators aligned in parallel in one direction, the wirings routed to the terminal box will be folded at larger number of points. According to the second invention, it now becomes possible to effectively avoid a risk of disconnection of the wirings in midway, after repetitive folding and unfolding. Also the fifth invention (the invention described in Claim 5) can give the same effects as the second invention.

Since the photovoltaic power generating apparatus of the third invention (the invention described in Claim 3) has the terminal box fixing part disposed at the center of the base, and has eight in total of the generators disposed thereon. Accordingly the apparatus, having a larger number of generators as compared with those composing the first or second invention, can increase the amount of power generation. Since the folding for stacking the individual diagonal generators above or behind the terminal box fixing part needs only two actions, so that the wirings may greatly be relieved from the risk of disconnection, like the inventions explained previously. Also the sixth invention (the invention described in Claim 6) can give the same effects as the third invention.

### BRIEF DESCRIPTION OF DRAWINGS

FIG. 1 is a plan view schematically illustrating an unfolded photovoltaic power generating apparatus of a first embodiment.

FIG. 2 is a plan view schematically illustrating a base.

FIG. 3 is a diagram of an internal circuit of a terminal box to which wirings are connected.

FIG. 4 is a perspective view schematically illustrating a partially folded photovoltaic power generating apparatus illustrated in FIG. 1.

FIG. 5 is a perspective view schematically illustrating a state of further folding subsequent to the state illustrated in FIG. 4.

FIG. 6 shows plan views schematically illustrating the individual modes of arrangement of the generators, wherein (A) represents a mode having the generators fixed laterally on both sides of the terminal box fixing part; (B) represents a mode having the generators fixed vertically on both sides of the terminal box fixing part; (C) and (D) represent modes having the generators fixed on three sides of the terminal box fixing part; (E) represents a mode having the generators fixed on four sides of the terminal box fixing part; and (F) represents a mode having a generator fixed in a diagonal direction from the terminal box fixing part.

FIG. 7 shows plan views schematically illustrating the individual modes of arrangement of the generators, wherein (G) and (H) represents modes based on the modes of arrangement of the generators illustrated in FIG. 1, and having additional generators on the upper and lower sides, and on the left and right sides, respectively.

FIG. 8 is a plan view schematically illustrating an unfolded photovoltaic power generating apparatus of a second embodiment.

### DESCRIPTION OF EMBODIMENTS

Best modes for carrying out this invention will be detailed below, referring to the attached drawings.

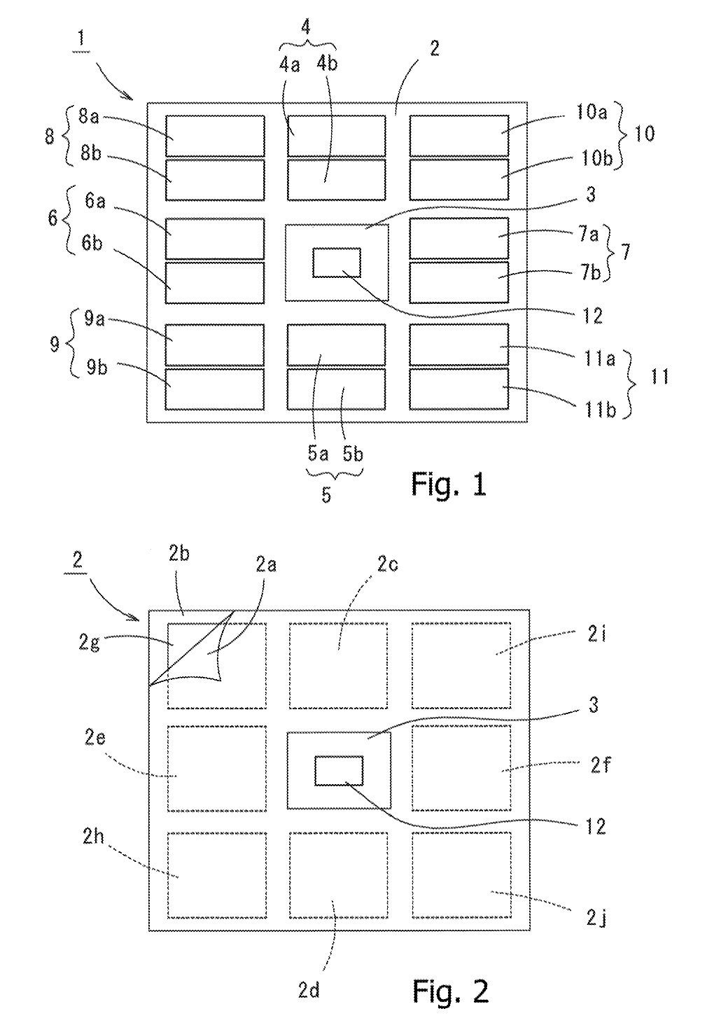

A photovoltaic power generating apparatus 1 of the first embodiment has, as illustrated in FIG. 1, a base 2 composed of a resin sheet (synthetic leather) formed into a quadrangular shape, a quadrangular terminal box fixing part 3 fixed at the center of the base 2, first to eighth photovoltaic power generator groups 4 to 11 fixed to the top face of the base 2, and a terminal box 12 fixed to the center of the terminal box fixing part 3.

In the photovoltaic power generating apparatus 1 of this embodiment, the base 2 is formed into a quadrangular shape as a whole as illustrated in FIG. 2, and is composed of a top sheet 2a and a back sheet 2b respectively made of resin, and first to eighth intermediate plates 2c to 2j disposed between the top sheet 2a and the back sheet 2b, and formed into a shape same as the later-described first to eighth photovoltaic power generator groups 4 to 11. The first to eighth intermediate plates 2c to 2j are slightly more rigid than the top sheet 2a, the back sheet 2b, and the first to eighth photovoltaic power generator groups 4 to 11, and have a thickness of 0.2 to 0.5 mm. The base 2 has a thickness of 1.0 mm or thinner locally at the portions where each of the first to eighth photovoltaic power generator groups 4 to 11 is disposed between the top sheet 2a and the back sheet 2b.

The terminal box fixing part 3 is formed into a quadrangular shape using an insulating resin such as epoxy resin. To the terminal box fixing part 3, a number of wirings, described later but not illustrated, are connected. At the center of the terminal box fixing part 3, the terminal box 12 is fixed.

As illustrated in FIG. 1, the first to eighth photovoltaic power generator groups 4 to 11 respectively have a shape similar to the terminal box fixing part 3, have a size slightly smaller than the terminal box fixing part 3, and are composed of one photovoltaic power generators 4a to 11a, other photovoltaic power generators 4b to 11b having same shape as the one photovoltaic power generators 4a to 11a, all of them being formed into a rectangular shape. The one photovoltaic power generators 4a to 11a and the other photovoltaic power generator 4b to 11b are respectively fixed to each other so as to align the long sides in parallel. Each of the one and other photovoltaic power generators 4a, 4b to 11a, 11b is a photovoltaic film. The first to eighth photovoltaic power generator groups 4 to 11 are fixed at positions corresponded to the positions where the first to eighth intermediate plates 2c to 2j are disposed.

The first photovoltaic power generator group 4 is disposed on the upper side of the terminal box fixing part 3, the second photovoltaic power generator group 5 is disposed on the lower side of the terminal box fixing part 3, the third photovoltaic power generator group 6 is disposed on the left side of the terminal box fixing part 3, the fourth photovoltaic power generator group 7 is disposed on the right side of the terminal box fixing part 3, the fifth photovoltaic power generator group 8 is disposed on the upper; left side of the terminal box fixing part 3, the sixth photovoltaic power generator group 9 is disposed on the lower left side of the terminal box fixing part 3, the seventh photovoltaic power generator group 10 is disposed on the upper right side of the terminal box fixing part 3, and the eighth photovoltaic power generator group 11 is disposed on the lower right side of the terminal box fixing part 3. In other words, in the photovoltaic power generating apparatus 1 of the first embodiment, the first and second photovoltaic power generator groups 4, 5 are disposed in two directions on the upper and lower sides of the terminal box fixing part 3, the third and fourth photovoltaic power generator groups 6, 7 are disposed in two directions on the left and right sides of the terminal box fixing part, and the fifth to eighth photovoltaic power generator groups 8 to 11 are disposed in diagonal directions around the terminal box fixing part 3.

There are slight spaces respectively between the first photovoltaic power generator group 4 and the fifth photovoltaic power generator group 8, between the first photovoltaic power generator group 4 and the seventh photovoltaic power generator group 10, between the second photovoltaic power generator group 5 and the sixth photovoltaic power generator group 9, between the second photovoltaic power generator group 5 and the eighth photovoltaic power generator group 11, between the third photovoltaic power generator group 6 and the fifth photovoltaic power generator group 8, between the third photovoltaic power generator group 6 and the sixth photovoltaic power generator group 9, between the fourth photovoltaic power generator group 7 and the seventh photovoltaic power generator group 10, and between the fourth photovoltaic power generator group 7 and the eighth photovoltaic power generator group 11. The entire part, or a part of these spaces is a portion where the wirings that electrically connect positive terminals and negative terminals formed in the first to eighth photovoltaic power generator groups 4 to 11 with the terminal box 12 are laid; and also a portion where the base 2 is repetitively folded or unfolded, typically between the terminal box fixing part 3 and the first to fourth photovoltaic power generator groups 4 to 7 so as to stack all of the first to eighth photovoltaic power generator groups 4 to 11 above or behind the terminal box fixing part 3, or so as to unstack the stacked first to eighth photovoltaic power generator groups 4 to 11 as illustrated in FIG. 1.

The one and other photovoltaic power generators 4a, 4b to 11a, 11b composing the first to eighth photovoltaic power generator groups 4 to 11 have positive terminals and negative terminals respectively formed at the same positions (reference signs not shown). The positive terminal and the positive terminal respectively formed in the one and other photovoltaic power generators 4a, 4b composing the first photovoltaic power generator group 4 are electrically connected by a wiring, and this (positive) wiring is connected to the terminal box 12. Meanwhile, the negative terminal and the negative terminal respectively formed in the one and other photovoltaic power generators 4a, 4b composing the first photovoltaic power generator group 4 are electrically connected by a wiring, and this (negative) wiring is connected to the terminal box 12. Such wiring is the same also for the second to eighth photovoltaic power generator groups 5 to 11, wherein the positive terminals and the negative terminals of each group are respectively connected by wirings, and both wirings are connected to the terminal box 12.

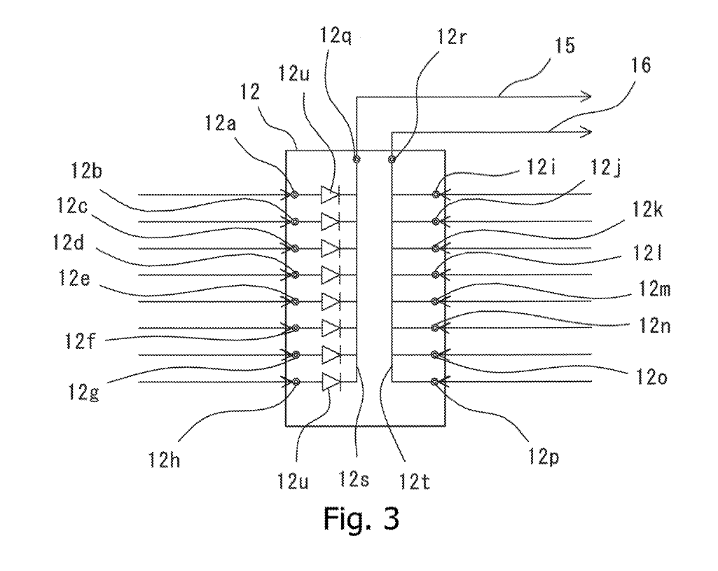

FIG. 3 is a circuit diagram schematically illustrating the terminal box 12 and the wirings connected to the terminal box 12 that are disposed on an unillustrated base. The terminal box 12 is formed in a quadrangular planar shape, and is approximately 10 to 12 mm thick. The terminal box 12 has, disposed along one long side thereof, first to eighth positive input terminals 12a to 12h to be respectively connected to a positive wiring having been connected to the first to eighth photovoltaic power generators 4 to 11, and also has, disposed along the other long side thereof, first to eighth negative input terminals 12i to 12p to be respectively connected to a negative wiring having been connected to the first to eighth photovoltaic power generators 5 to 12. The terminal box 12 also has, disposed along one short side thereof, a positive output terminal 12q, and a negative output terminal 12r disposed next to the positive output terminal 12q. The first to eighth positive input terminals 12a to 12h are commonly connected to a single positive wiring 12s, and the end of the positive wiring 12s is connected to the positive output terminal 12q. Meanwhile, the first to eighth negative input terminals 12i to 12p are commonly connected to a single negative wiring 12t, and the end of the negative wiring 12t is connected to the negative output terminal 12r. Between the positive wiring 12s and each of the first to eighth positive input terminals 12a to 12h, there is provided a diode 12u for backflow prevention. A positive output cable 15 to be connected to an unillustrated power storage unit is connected to the positive output terminal 12q positioned on the terminal box 12, and a negative output cable 16 to be connected to the power storage unit is connected to the negative output terminal 12r.

A method of folding the above-described photovoltaic power generating apparatus 1 of the first embodiment will be briefed.

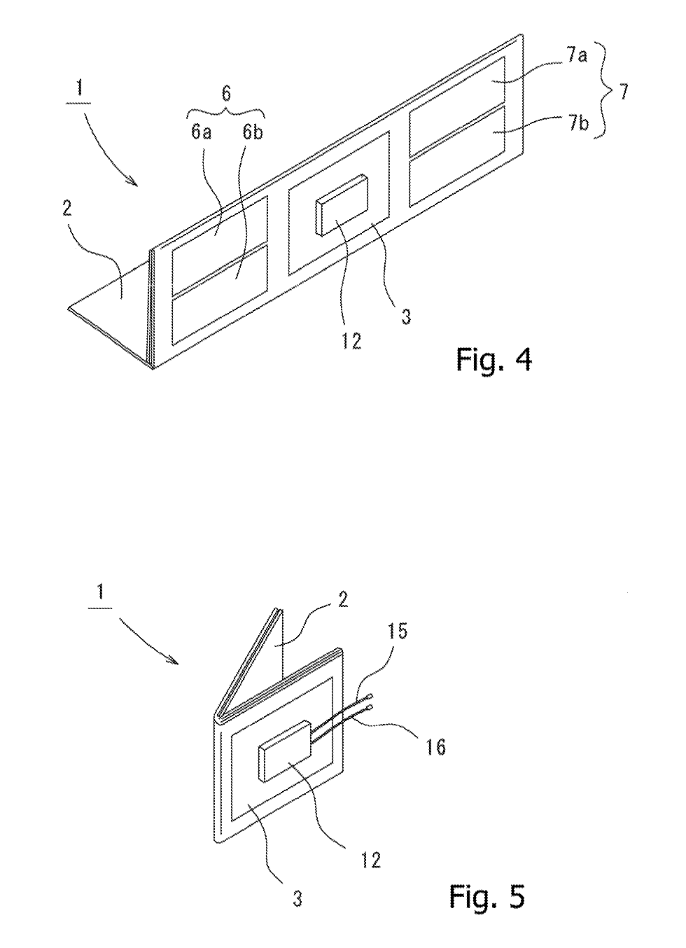

According to this method of folding, starting from a (unfolded) state illustrated in FIG. 1, the base 2 is folded four times along any of four sides around the terminal box fixing part 3. In this embodiment, since the terminal box 12 was fixed on the terminal box fixing part 3 (on the top face of the terminal box fixing part 3), the base 2 is folded outwardly along all of four sides around the terminal box fixing part 3. In this way, all of the first to eighth photovoltaic power generator groups 4 to 11 are stacked behind the terminal box fixing part 3. For example, the base 2 is first folded between the terminal box fixing part 3 and the first photovoltaic power generator group 4 along their sides, so as to stack the first photovoltaic power generator group 4 behind the terminal box fixing part 3, the fifth photovoltaic power generator group 8 behind the third photovoltaic power generator group 6, and the seventh photovoltaic power generator group 10 behind the fourth photovoltaic power generator group 7, respectively. The base 2 is then folded between the terminal box fixing part 3 and the second photovoltaic power generator group 5 along their sides, so as to stack the second photovoltaic power generator group 5 on the back face side of the base 2 where the first photovoltaic power generator group 4 has already been placed thereon, the sixth photovoltaic power generator group 9 behind the fifth photovoltaic power generator group 8, and the eighth photovoltaic power generator group 11 behind the base 2 where the seventh photovoltaic power generator group 10 has already been placed, respectively (see FIG. 4). Next, the base 2 is folded between the terminal box fixing part 3 and the third photovoltaic power generator group 6 along their sides, so as to stack the fifth photovoltaic power generator group 3 and the sixth photovoltaic power generator group 9 behind the second photovoltaic power generator group 5. The base 2 is also folded between the terminal box fixing part 3 and the fourth photovoltaic power generator group 7 along their sides, so as to stack the seventh photovoltaic power generator group 10 and the eighth photovoltaic power generator group 11 behind the third photovoltaic power generator group 6 where the fifth photovoltaic power generator group 8 and the sixth photovoltaic power generator group 9 have already been placed (see FIG. 5). In this way, all of the first to eighth photovoltaic power generator groups 4 to 11 are stacked behind the terminal box fixing part 3, while placing at the top the terminal box fixing part 3 having the terminal box 12 fixed to the top face thereof. Note that, for the case where the terminal box 12 is disposed on the back face of the terminal box fixing part 3, it will be good enough to fold the base 2 inwardly along all of four sides around the terminal box fixing part 3.

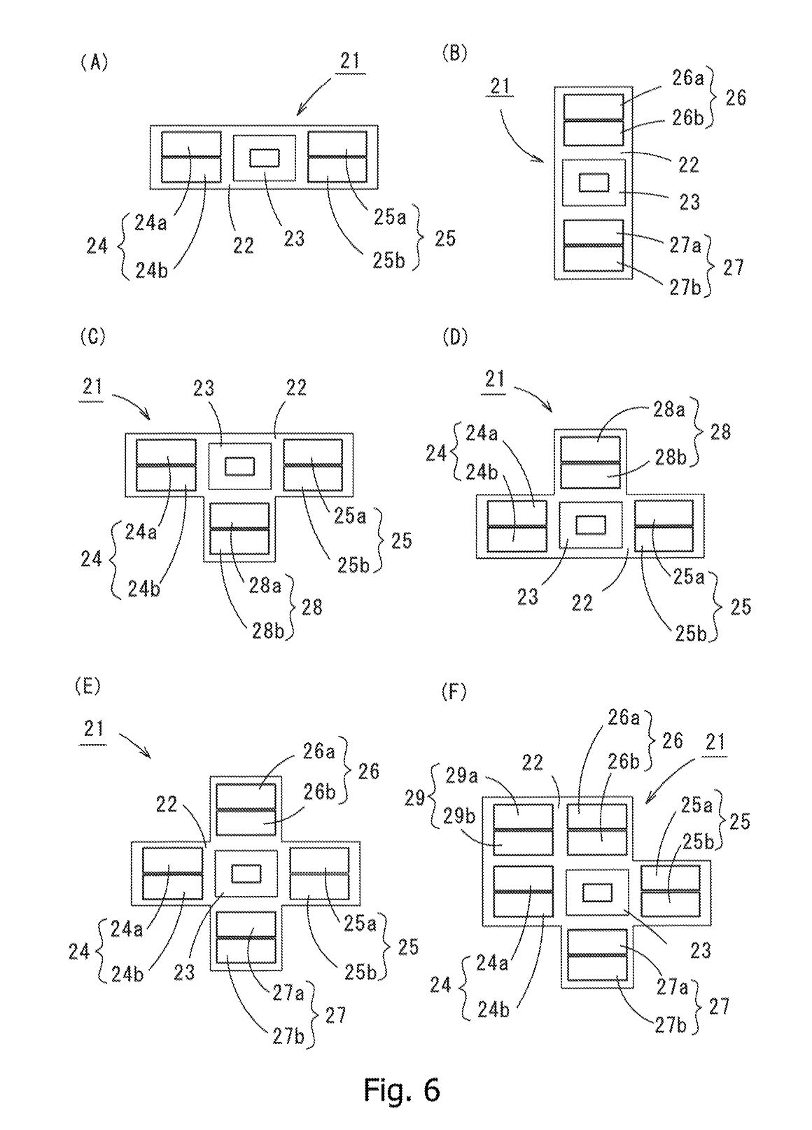

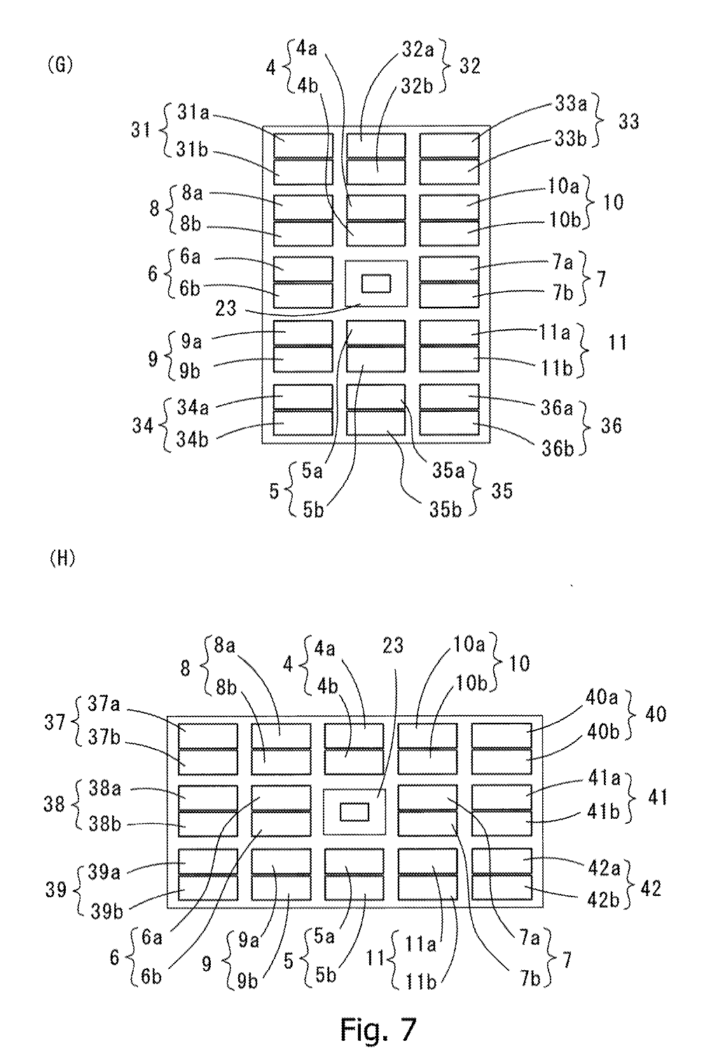

Having been described the embodiment of the photovoltaic power generating apparatus 1 where the terminal box fixing part 3 was fixed at the center of the base 2 and the first to eighth generators 4 to 11 were disposed around the terminal box fixing part 3, the generators in this invention will suffice if they are disposed at least in two directions out of four directions including upper, lower, left and right directions around the terminal box fixing part 3. For example, the apparatus may be the one (photovoltaic power generating apparatus 21) schematically illustrated in FIG. 6(A), having on the top face of a base 22 a first photovoltaic power generator group 24 fixed on the left of the terminal box fixing part 23, and having a second photovoltaic power generator group 25 fixed on the right; or may be the one (photovoltaic power generating apparatus 21) illustrated in FIG. 6(B), having a first photovoltaic power generator group 26 fixed on the upper side of the terminal box fixing part 23, and having a second photovoltaic power generator group 27 fixed on the lower side. The apparatus may also be the one illustrated in FIG. 6(C), having a third photovoltaic power generator group 28 on the lower side of the terminal box fixing part 23 composing the photovoltaic power generating apparatus 21 illustrated in FIG. 6 (A); or may be the one illustrated in FIG. 6(D), having the third photovoltaic power generator group 29 fixed on the upper side of the terminal box fixing part 23. The apparatus may still also be the one illustrated in FIG. 6(E), having the photovoltaic power generator groups (first to fourth photovoltaic power generator groups 24 to 27) fixed on the left, right, upper and lower sides of the terminal box fixing part 23. The apparatus may still also be the one illustrated in FIG. 6(F), having the fifth diagonal photovoltaic power generator group 29 composing this invention, in the obliquely upper left direction from the terminal box fixing part 23 composing the photovoltaic power generating apparatus 21 illustrated in FIG. 6(E). The apparatus may still also be the one illustrated in FIG. 7(G), having a ninth photovoltaic power generator group 31 fixed on the upper side of the fifth photovoltaic power generator group 8 composing the photovoltaic power generating apparatus 1 illustrated in FIG. 1, having a tenth photovoltaic power generator group 32 fixed on the upper side of the first photovoltaic power generator group 4, having an eleventh photovoltaic power generator group 33 fixed on the upper side of the seventh photovoltaic power generator group 10, and, having a twelfth photovoltaic power generator group 34 fixed on the lower side of the sixth photovoltaic power generator group 9, having a thirteenth photovoltaic power generator group 35 fixed on the lower side of the second photovoltaic power generator group 5, and having a fourteenth photovoltaic power generator group 36 fixed on the lower side of the eighth photovoltaic power generator group 11; or may be the one illustrated in FIG. 7(H), having a ninth photovoltaic power generator group 37 fixed on the left side of the fifth photovoltaic power generator group 8, having a tenth photovoltaic power generator group 38 fixed on the left side of the third photovoltaic power generator group 6, having an eleventh photovoltaic power generator group 39 fixed on the left side of the sixth photovoltaic power generator group 9, having a twelfth photovoltaic power generator group 40 fixed on the right side of the seventh photovoltaic power generator group 10, having a thirteenth photovoltaic power generator group 41 fixed on the right side of the fourth photovoltaic power generator group 7, and having a fourteenth photovoltaic power generator group 42 fixed on the right side of the eighth photovoltaic power generator group 11.

According to the photovoltaic power generating apparatuses 1, 21 described above, not only that all the generators (reference signs not given here) may be positioned (stacked) behind the terminal box fixing parts 3, 23 by folding the base 2 per se, but also that total distance between the terminal box 12 and each of the photovoltaic power generators will be shorter than the total distance in the conventional photovoltaic power generating apparatus having the individual photovoltaic power generators aligned in parallel in one direction. Since the total length of the wirings that electrically connect the terminal box with each of the photovoltaic power generators composing the photovoltaic generator groups may be shortened in this way, so that the electric resistance may greatly be suppressed. In the photovoltaic power generating apparatuses 1, 21 of this invention, in the process of stacking (by folding) the individual generators so as to place them behind the terminal box fixing part 3, 23, or in the process of unstacking the generators having been stacked behind the terminal box fixing part 3, 23, since the wirings between the terminal box 12 and the individual photovoltaic generators are stacked or unstacked at considerably reduced number of portions as compared with the conventional photovoltaic power generating apparatus having the individual photovoltaic power generators aligned in parallel in one direction, so that the wirings between the terminal box fixing parts 3, 23 and the individual photovoltaic power generator groups may greatly be relieved from the risk of disconnection.

Although having described above referring to the drawings that the photovoltaic power generating apparatus 1 of the first embodiment has as the constituent thereof a single base 2, and that the individual photovoltaic power generator groups (reference signs not given here) are stacked by folding above or behind the terminal box fixing part 3 by folding the base 2 per se, this invention may alternatively be configured by using a certain number of, rather than a single, quadrangular plate-like bases, where such number being corresponded to the constitutive generators, and the every adjacent bases and the terminal box fixing part are respectively joined using hinges.

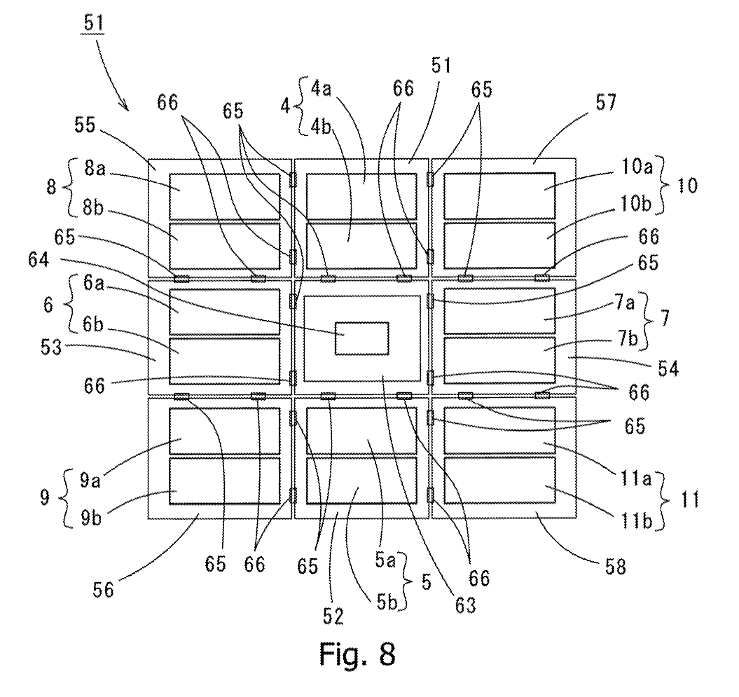

More specifically, a photovoltaic power generating apparatus 51 of the second embodiment has, as illustrated in FIG. 8, first to eighth bases (eight bases 52 to 59 in total), and a terminal box fixing part 63 surrounded by the first to eighth bases 52 to 59, where every adjacent ones of the first to eighth bases 52 to 59 and the terminal box fixing part 63 are joined by two each hinges 65, 66 in a foldable manner. The first to eighth bases 52 to 59 respect lovely have, fixed on the surfaces (top faces) thereof, the first to eighth photovoltaic power generator groups 4 to 11, and the terminal box fixing part 63 has, fixed on the surface (top face) thereof, a terminal box 64.

Also with the photovoltaic power generating apparatus 51 of the second embodiment, it now becomes possible to stack all generators 4 to 11 behind or above the terminal box fixing part 63, in the same way as with the photovoltaic power generating apparatus 1 of the first embodiment.

Although having described in the embodiments that the photovoltaic power generator groups 4 to 11, having the photovoltaic power generators 4a to 11a and the other photovoltaic power generators 4b to 11b respectively aligned in parallel with respect to their long sides, were fixed on the bases 2 and 51 to 58, the generator composing this invention may alternatively have a single photovoltaic power generator fixed thereon.

### REFERENCE SIGNS LIST

1 photovoltaic power generating apparatus
2 base
3 terminal box fixing part
4 first photovoltaic power generator group
4a one photovoltaic power generator
4b other photovoltaic power generator;
5 second photovoltaic power generator group
5a one photovoltaic power generator
5b other photovoltaic power generator
6 third photovoltaic power generator group
6a one photovoltaic power generator
6b other photovoltaic power generator
7 fourth photovoltaic power generator group
7a one photovoltaic power generator
7b other photovoltaic power generator
8 fifth photovoltaic power generator group
8a one photovoltaic power generator
8b other photovoltaic power generator
9 sixth photovoltaic power generator group
9a one photovoltaic power generator
9b other photovoltaic power generator
10 seventh photovoltaic power generator group
10a one photovoltaic power generator
10b other photovoltaic power generator
11 eighth photovoltaic power generator group
11a one photovoltaic power generator
11b other photovoltaic power generator
12 terminal box
21 photovoltaic power generating apparatus
22 base
23 terminal box fixing part
24 first photovoltaic power generator group
24a one photovoltaic power generator
24b other photovoltaic power generator
25 second photovoltaic power generator; group
25a one photovoltaic power generator
25b other photovoltaic power generator
51 photovoltaic power generating apparatus
51 first base
52 second base
53 third base
54 fourth base
55 fifth base
56 sixth base
57 seventh base
58 eighth base
63 terminal box fixing part
64 terminal box
65 one hinge
66 other hinge

1. A photovoltaic power generating apparatus comprising:
a base composed of a foldable sheet body such as cloth, resin sheet or the like;
a quadrangular terminal box fixing part disposed on the base;
a terminal box disposed either on the top face or the back face of the terminal box fixing part; and
upper and/or lower generator(s), or, left and/or right generator(s) individually formed into a quadrangular shape, comprising a single photovoltaic power generator, and disposed on the top face of the base in at least two directions out of four directions including upper, lower, left and right directions around the terminal box fixing part; or, upper and/or lower generators), or, left and/or right generators) individually comprising a single photovoltaic power generator group that comprises a plurality of photovoltaic power generators and formed into a quadrangular shape as a whole, and
all of the generators are stackable by folding on the top face side or the back face side of the terminal box fixing part.

2. The photovoltaic power generating apparatus according to claim 1, further comprising a diagonal generator disposed on the top face of the base, in any one direction out of four directions including obliquely upper left, obliquely lower left, obliquely upper right and obliquely lower right directions around the terminal box fixing part, a predetermined distance away from the upper and/or lower generators), or, left and/or right generator(s).

3. The photovoltaic power generating apparatus according to claim 1,
wherein the base has a quadrangular external shape, the terminal box fixing part is disposed at the center of the base, and the individual generators are disposed so as to surround the terminal box fixing part.

4. A photovoltaic power generating apparatus comprising:
a terminal box fixing part formed into a quadrangular shape;
a terminal box disposed either on the top face or the back face of the terminal box fixing part;
upper and/or lower base(s), or, left and/or right base(s) disposed in at least two directions out of four directions including upper, lower, left and right directions around the terminal box fixing part, individually formed into a quadrangular shape and in a plate form, and joined with the terminal box fixing part using hinges or flexible sheet bodies; and
generators respectively disposed on the top faces of the individual bases, each comprising a single photovoltaic power generator; or, generators each comprising a single photovoltaic power generator group that comprises a plurality of photovoltaic power generators and formed into a quadrangular shape as a whole, and
all of the bases are stackable by folding on the top face side or the back face side of the terminal box fixing part.

5. The photovoltaic power generating apparatus according to claim 4, further comprising a diagonal base joined to the upper and/or lower base(s), or, to tire left and/or right base(s) using a hinge or a flexible sheet body, in any one direction out of four directions including obliquely upper left, obliquely lower left, obliquely upper right and obliquely lower right directions around the terminal box fixing part, and
the diagonal base has, disposed on the top face thereof, a generator comprising a single photovoltaic power generator, or, a generator comprising a single photovoltaic power generator group that comprises a plurality of photovoltaic power generators and formed into a quadrangular shape as a whole.

6. The photovoltaic power generating apparatus according to claim 4, wherein the bases that are respectively joined using the hinges or the flexible sheet bodies collectively have a quadrangular external shape as a whole, and the terminal box fixing part is disposed at the center of the whole bases.

7. The photovoltaic power generating apparatus according to claim 2,
wherein the base has a quadrangular external shape, the terminal box fixing part is disposed at the center of the base, and the individual generators are disposed so as to surround the terminal box fixing part.

8. The photovoltaic power generating apparatus according to claim 5, wherein the bases that are respectively joined using the hinges or the flexible sheet bodies collectively have a quadrangular external shape as a whole, and the terminal box fixing part is disposed at the center of the whole bases.
